(19) United States
(12) Patent Application Publication
(10) Pub. No.: US 2021/0202738 A1
(43) Pub. Date: Jul. 1, 2021

(54) METHOD AND APPARATUS WITH A DETERMINATION OF A LOW SUPPLY VOLTAGE OF A SEMICONDUCTOR CHIP

(71) Applicant: Samsung Electronics Co., Ltd., Suwon-si (KR)

(72) Inventors: Dong-Uk RYU, Seongnam-si (KR); Wooseok CHANG, Seoul (KR)

(73) Assignee: Samsung Electronics Co., Ltd., Suwon-si (KR)

(21) Appl. No.: 16/922,066

(22) Filed: Jul. 7, 2020

(30) Foreign Application Priority Data
Dec. 26, 2019 (KR) 10-2019-0175107

(51) Int. Cl. H01L 29/78; G06F 1/3234; G06F 1/3296

(52) U.S. Cl. CPC H01L 29/7826; G06F 1/3225; G06F 1/3296; G06F 1/3275

(57) ABSTRACT

A processor-implemented method performed by an electronic apparatus includes determining a second voltage obtained by reducing a first voltage by a voltage having a preset magnitude, controlling a target semiconductor chip such that the target semiconductor chip performs a preset target task based on the second voltage, determining whether a result of the target task is the same as a reference result preset for the target task, and determining the first voltage as being a low supply voltage of the target semiconductor chip, in response to the result differing from the reference result.

### CROSS-REFERENCE TO RELATED APPLICATIONS

This application claims the benefit under 35 USC § 119(a) of Korean Patent Application No. 10-2019-0175107, filed on Dec. 26, 2019, in the Korean Intellectual Property Office, the entire disclosure of which is incorporated herein by reference for all purposes.

### BACKGROUND

### 1. Field

The following description relates to a method and apparatus with a determination of a low supply voltage of a semiconductor chip.

### 2. Description of Related Art

A low supply voltage LVcc is a voltage at which a semiconductor chip operates normally and such a low supply voltage generally tends to increase in proportion to a period of time during which the semiconductor chip operates. Accordingly, a voltage actually supplied to the semiconductor chip may be determined based on the low supply voltage LVcc. A difference between the low supply voltage LVcc and the voltage actually supplied to the semiconductor chip is referred to as a voltage margin. When such a voltage margin increases, the semiconductor chip may operate normally for a relatively long period of time. However, because an amount of power consumed by the semiconductor chip increases as the voltage margin increases, the voltage actually supplied to the semiconductor chip may be determined based on an increase in the amount of power consumed by the semiconductor chip.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a processor-implemented method performed by an electronic apparatus includes determining a second voltage obtained by reducing a first voltage by a voltage having a preset magnitude, controlling a target semiconductor chip such that the target semiconductor chip performs a preset target task based on the second voltage, determining whether a result of the target task is the same as a reference result preset for the target task, and determining the first voltage as being a low supply voltage of the target semiconductor chip, in response to the result differing from the reference result.

The target semiconductor chip may include one or more processors of the electronic apparatus or one or more processors of another electronic apparatus.

In response to the one or more processors comprising a multi-core processor, the target semiconductor chip may include a first core of the multi-core processor and the low supply voltage of the target semiconductor chip may be determined by a second core of the multi-core processor.

The one or more processors may include a central processing unit (CPU).

The target semiconductor chip may include a memory of the electronic apparatus or a memory of another electronic apparatus.

The memory of the electronic apparatus may include a cache memory.

The electronic apparatus may be fabricated as a system on chip (SoC).

The electronic apparatus may be mounted on a vehicle.

The method may further include resetting the target semiconductor chip, in response to the target semiconductor chip failing to generate a result of the preset target task.

The method may further include determining a degree of degradation of the target semiconductor chip based on the low supply voltage of the target semiconductor chip, and adjusting a task schedule for the target semiconductor chip, in response to the degree of degradation exceeding a reference degree of degradation preset for the target semiconductor chip.

The method may be performed in response to a determined current point in time being a preset target point in time.

The target point in time may be included in a sequence of points in time in which the electronic apparatus is powered off.

In another general aspect, a non-transitory computer-readable storage medium stores instructions that, when executed by a processor, cause the processor to perform the method described above.

In another general aspect, an electronic apparatus includes one or more processors configured to determine a second voltage obtained by reducing a first voltage by a voltage having a preset magnitude, control a target semiconductor chip such that the target semiconductor chip performs a preset target task based on the second voltage, determine whether a result of the target task is the same as a reference result preset for the target task, and determine the first voltage as a low supply voltage of the target semiconductor chip, in response to the result being different from the reference result.

The target semiconductor chip may include a processor of the electronic apparatus or a processor of another electronic apparatus.

In response to the one or more processors including a multi-core processor, the target semiconductor chip may be a first core of the multi-core processor and the low supply voltage of the target semiconductor chip may be determined by a second core of the multi-core processor.

The one or more processors may include a central processing unit (CPU).

The target semiconductor chip may include a memory of the electronic apparatus or a memory of another electronic apparatus.

The electronic apparatus may be mounted on a vehicle.

The one or more processors may be further configured to perform resetting the target semiconductor chip, in response to the target semiconductor chip failing to generate a result of the preset target task.

The apparatus may further include a memory storing instructions, which, when executed by the one or more processors, configure the one or more processors to perform the determination of the second voltage, the controlling, the determination of whether a result of the target task is the same as a reference result, and the determination of the first voltage.

In another general aspect, a processor-implemented method performed by an electronic apparatus, includes determining a second voltage obtained by reducing a first voltage by a voltage having a preset magnitude, controlling a target semiconductor chip that is a first core of a multi-core processor, such that the target semiconductor chip performs a preset target task based on the second voltage, determining whether a result of the target task is the same as a reference result preset for the target task, and determining the first voltage as being a low supply voltage of the target semiconductor chip, in response to the result differing from the reference result, wherein the low supply voltage of the target semiconductor chip is determined by a second core of the multi-core processor.

The electronic apparatus may be fabricated as a system on chip (SoC).

The electronic apparatus may be mounted on a vehicle.

The method may further include resetting the target semiconductor chip, in response to the target semiconductor chip failing to generate a result of the preset target task.

Other features and aspects will be apparent from the following detailed description, the drawings, and the claims.

### BRIEF DESCRIPTION OF THE DRAWINGS

FIG. 1 illustrates a lifetime of a semiconductor chip based on increasing speeds of different low supply voltages LVcc, according to one or more examples.

FIG. 2 illustrates a configuration of an electronic apparatus for determining LVcc of a semiconductor chip, according to one or more examples.

FIG. 3 illustrates a method of determining an LVcc of a semiconductor chip, according to one or more examples.

FIG. 4 illustrates a target core with an LVcc to be determined and a core for determining the LVcc of the target core, when a processor of an electronic apparatus is a multi-core processor, according to one or more examples.

FIG. 5 is a flowchart illustrating a method of monitoring a target semiconductor chip and resetting the target semiconductor chip, according to one or more examples.

FIG. 6 illustrates a method by which an electronic apparatus determines an LVcc of a semiconductor chip of another electronic apparatus, according to one or more examples.

FIG. 7 is a flowchart illustrating a method of adjusting a task schedule of a target semiconductor chip based on an LVcc of the target semiconductor chip, according to one or more examples.

FIG. 8 illustrates a configuration of a vehicle including an electronic apparatus, according to one or more examples.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application, and are not to be interpreted in an idealized or overly formal sense unless expressly so defined herein.

Terms such as “including” or “comprising” used in the embodiments should not be construed as necessarily including all of various components, or various operations described in the specification, and it should be construed that some of the components or some of the operations may not be included or may further include additional components or operations. The use of the term “may” herein with respect to an example or embodiment (e.g., as to what an example or embodiment may include or implement) means that at least one example or embodiment exists where such a feature is included or implemented, while all examples are not limited thereto.

In the specification, expressions or terms such as “include,” “comprise,” “including,” and “comprising” should not be construed as always including all specified elements, processes, or operations, but may be construed as not including some of the specified elements, processes, or operations, or further including other elements, processes, or operations.

Hereinafter, example embodiments will be described in detail with reference to the accompanying drawings. However, embodiments may be implemented in various forms and should not be construed as being limited to the embodiments set forth herein.

Various modifications may be made to the examples. Here, the examples are not construed as limited to the disclosure and should be understood to include all changes, equivalents, and replacements within the idea and the technical scope of the disclosure.

The terminology used herein is for the purpose of describing particular examples only and is not to be limiting of the examples. As used herein, the singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

When describing the examples with reference to the accompanying drawings, like reference numerals refer to like constituent elements and a repeated description related thereto will be omitted. In the description of examples, detailed description of well-known related structures or functions will be omitted when it is deemed that such description will cause ambiguous interpretation of the present disclosure.

The following description relates to a technology of determining a low supply voltage LVcc of a semiconductor chip, and more particularly, to a technology of determining a low supply voltage LVcc of a semiconductor chip based on a result obtained by performing a task on the semiconductor chip.

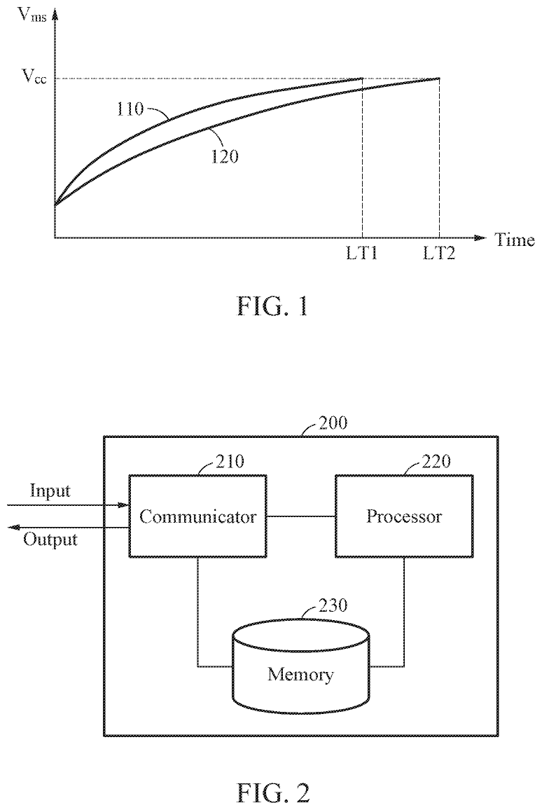

FIG. 1 illustrates a lifetime of a semiconductor chip based on increasing speeds of different low supply voltages LVcc, according to one or more examples.

In one or more examples, despite using the same semiconductor chips, a lifetime of a semiconductor chip may vary, depending on various requirements of fabrication of the semiconductor chip. For example, the lifetime of the semiconductor chip may be affected by a position of a material on a wafer used for fabricating the semiconductor chip.

In other examples, lifetimes of semiconductor chips having the same specifications may also vary depending on the usage environments of the chips. For example, when an operating time, a temperature and a voltage of a semiconductor chip increase, a lifetime of the semiconductor chip may decrease accordingly.

A lifetime of a semiconductor chip is an amount of time required until a low supply voltage, hereinafter, represented as “LVcc,” of the semiconductor chip reaches an actual supply voltage Vcc. A lifetime of a semiconductor chip 110 having a faster increase speed of LVcc over time by comparison to a semiconductor chip 120 may be less than a lifetime of the semiconductor chip 120. When the semiconductor chip 110 processes a greater number of tasks than that of the semiconductor chip 120, even though the semiconductor chips 110 and 120 may have the same specifications, the lifetime of the semiconductor chip 110 may be less than the lifetime of the semiconductor chip 120.

In one or more examples, when the semiconductor chips 110 and 120 are included in the same electronic apparatus, a lifetime of the electronic apparatus may depend on the lifetime of the semiconductor chip 110 that is less than that of the semiconductor chip 120. When a schedule of tasks is adjusted to allow the lifetimes of the semiconductor chips 110 and 120 to be similar to one another, the lifetime of the electronic apparatus may increase accordingly, due to the adjustment. To this end, a residual lifetime of each of the semiconductor chips 110 and 120 may be measured. The residual lifetime may be determined by determining a present LVcc of each of the semiconductor chips 110 and 120.

Subsequently, a method of determining LVcc of a semiconductor chip will be described in greater detail below, with reference to FIGS. 2 through 6.

FIG. 2 illustrates a configuration of an electronic apparatus 200 for determining an LVcc of a semiconductor chip, according to one or more examples.

Referring to FIG. 2, the electronic apparatus 200 may include a communicator 210, a processor 220 and a memory 230, according to one or more non-limiting examples.

The communicator 210 may be connected to the processor 220 and the memory 230 and may also be configured to transmit and receive data to and from the processor 220 and the memory 230. The communicator 210 may be connected to an external device and may also be configured to transmit output data and receive input data to and from the external device. In the following description, the expression “transmitting and receiving A” refers to transmitting and receiving of data or information representing “A.”

The communicator 210 may be implemented, for example, as circuitry in the electronic apparatus 200. In one or more examples, the communicator 210 may include an internal bus and an external bus. In other examples, the communicator 210 may be a device configured to connect the electronic apparatus 200 to an external device. In such an example, the communicator 210 may be, for example, an interface or an interface device. The communicator 210 may receive data from the external device and may transmit data to the processor 220 and the memory 230.

The processor 220 may process data received by the communicator 210 and data stored in the memory 230. The term “processor,” as used herein, may be a hardware-implemented data processing device including a circuit that may be physically structured to execute desired operations. For example, the desired operations may include instructions, that when executed by the processor, cause the processor to perform methods according to examples. The hardware-implemented data processing device may include, for example, a microprocessor, a central processing unit (CPU), a processor core, a multi-core processor, a multiprocessor, an application-specific integrated circuit (ASIC), and a field-programmable gate array (FPGA), and/or multiple processors, according to various non-limiting examples.

The processor 220 may execute a computer-readable code, such as software instructions, stored in a memory, (for example, the memory 230), and may execute such instructions by the processor 220.

The memory 230 may store data received by the communicator 210 and data processed by the processor 220. In one or more examples, the memory 230 may store instructions, such as instructions for a program, an application, or software. In such an example, the stored program may be coded to determine an LVcc of a semiconductor chip and may be conform to a syntax executable by the processor 220.

The memory 230 may include, for example, any one or any combination of any two or more of a volatile memory, a nonvolatile memory, a random access memory (RAM), a flash memory, a hard disk drive and an optical disc drive, as non-limiting examples, but other hardware that is able to store information may be used for memory 230.

The memory 230 may store an instruction set (for example, a group of software instructions) used to operate the electronic apparatus 200. The instruction set used to operate the electronic apparatus 200 may be executed by the processor 220.

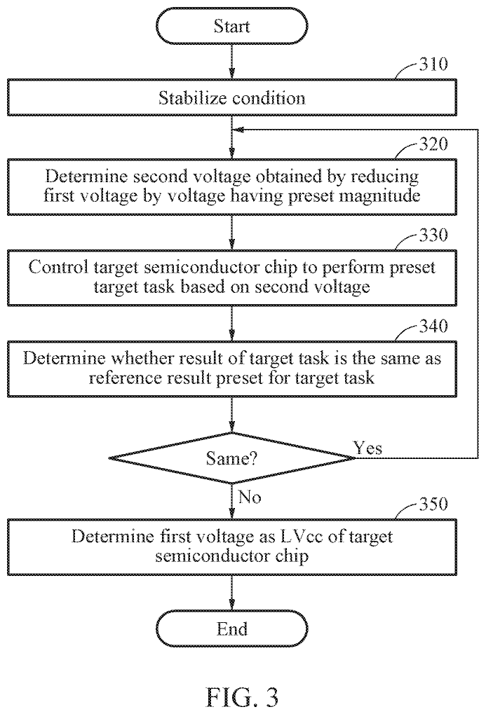

The communicator 210, the processor 220 and the memory 230 will be described in greater detail below with reference to FIGS. 3 through 8.

FIG. 3 illustrates a method of determining LVcc of a semiconductor chip, according to one or more examples.

Operations 310 through 350 of FIG. 3 are performed by, for example, the electronic apparatus 200, as described above with reference to FIG. 2. For example, the electronic apparatus 200 may be fabricated using system on chip (SoC) techniques.

In operation 310, the electronic apparatus 200 may stabilize a condition of a target semiconductor chip, of which an LVcc is to be determined. For example, the condition of the target semiconductor chip may be a temperature of the target semiconductor chip, but examples are not limited to such an enumerated example, and other information may be used as the condition of the target semiconductor chip.

In operation 320, the electronic apparatus 200 may determine a second voltage obtained by reducing a first voltage by a voltage having a preset magnitude. In one non-limiting example, the first voltage may be a voltage Vcc that is actually supplied to the target semiconductor chip. In another non-limiting example, the first voltage may be a voltage at which the target semiconductor chip operates normally.

In operation 330, the electronic apparatus 200 may control the target semiconductor chip such that the target semiconductor chip performs a preset target task, based on the second voltage.

In one or more examples, the target semiconductor chip may be a processor. The processor may include a CPU. The CPU may include, for example, a CPU for a personal computer (PC) and/or a CPU for a mobile terminal, as non-limiting examples. For example, the target semiconductor chip may be a processor of the electronic apparatus 200 or may be a processor of another electronic apparatus. When the target semiconductor chip is a processor of the electronic apparatus 200, the electronic apparatus 200 may automatically perform a target task corresponding to the target semiconductor chip. When the target semiconductor chip is a processor of another electronic apparatus, the electronic apparatus 200 may input an instruction or a command to perform a task to the target semiconductor chip, accordingly.

In another example, the target semiconductor chip may be a memory. The memory may include a storage device and a cache memory. For example, the target semiconductor chip may be a memory of the electronic apparatus 200 or a memory of another electronic apparatus, as non-limiting examples.

The preset target task may be a task used to verify whether the target semiconductor chip operates in a normal state. In one example, when the target semiconductor chip is a processor, the target task may include program operations such as ADD, BL, CMP, LDC, LDR, STC, STR and MCR, where these represent program operations, such from an instruction set such as ARM, as a non-limiting example and other operations may be used in other examples. In another example, when the target semiconductor chip is a memory, the target task may include programs such as zip/unzip (for compression and decompression), iozone (a file system benchmark utility), tiotest (a threaded i/o benchmark test) and memtester (a userspace memory testing program) that use the memory intensively for a relatively short period of time.

In operation 340, the electronic apparatus 200 may determine whether a result of the target task is the same as a reference result preset for the target task. The reference result may be a result generated when the target semiconductor chip normally performs the target task, such as under normal conditions or with normal results. For example, the result may be data.

When a generated result is the same as the reference result, the target semiconductor chip may be considered to be operating normally under the second voltage.

When the generated result differs from the reference result, the target semiconductor chip may be regarded to operate annormally under the second voltage. An example in which the generated result may considered to be different from the reference result may be an example in which the second voltage is low enough to generate a result normally, even though the target semiconductor chip operates abnormally.

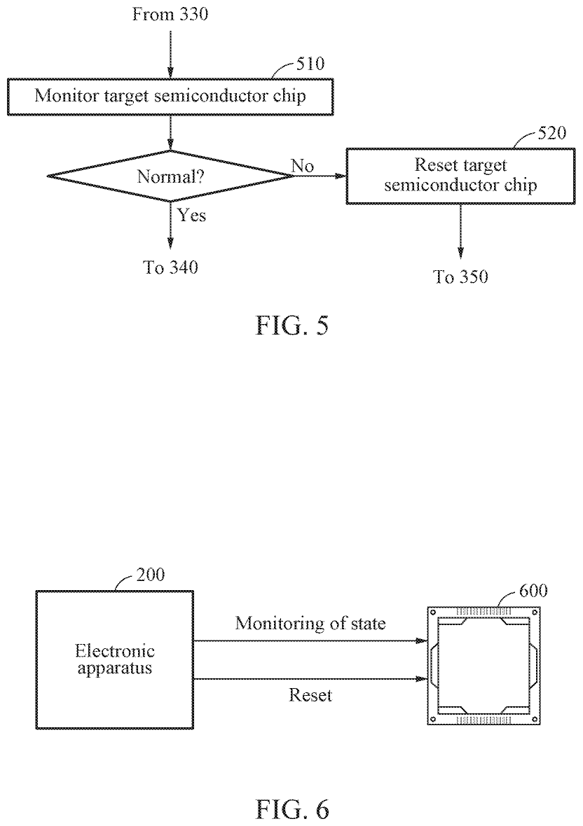

When the second voltage is less than an LVcc of the target semiconductor chip, a result of the target semiconductor chip may not be generated, and a system may be shut down accordingly. A method of preventing a system shutdown will be described in greater detail below, with reference to FIG. 5.

When the target semiconductor chip operates normally under the second voltage, operations 320 through 340 may be performed again. For example, a third voltage may be determined by reducing the second voltage by a voltage having a preset magnitude, and whether the target semiconductor chip operates normally under the third voltage may be determined as well.

In operation 350, the electronic apparatus 200 may determine the first voltage as being an LVcc of the target semiconductor chip, when the generated result is different from the reference result. For example, the first voltage may be a voltage at which the target semiconductor chip operates normally.

When a plurality of target semiconductor chips are provided for consideration, operations 310 through 350 may be performed on each of the target semiconductor chips in order to determine an LVcc for each of the target semiconductor chips.

A life expectancy of a target semiconductor chip may be predicted based on the determined LVcc of the target semiconductor chip. For example, a graph of LVcc of the target semiconductor chip over time may be generated based on appropriate measurements, and the life expectancy of the target semiconductor chip may be predicted based on the graph. When an electronic apparatus including the target semiconductor chip includes a plurality of target semiconductor chips, life expectancies of the plurality of target semiconductor chips may be compared to each other.

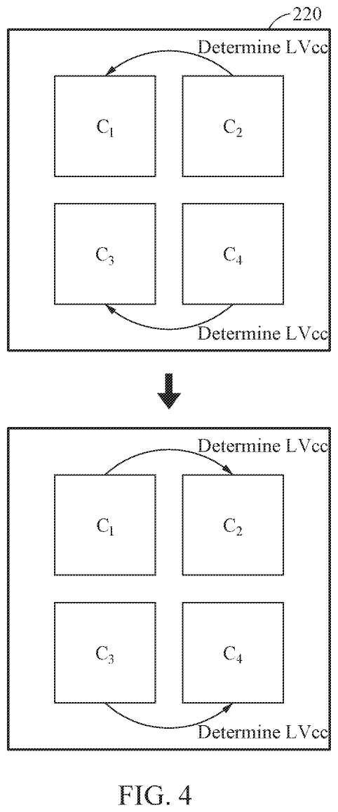

FIG. 4 illustrates a target core with an LVcc to be determined and a core for determining LVcc of the target core, when a processor of an electronic apparatus is a multi-core processor, according to one or more examples.

In one or more examples, when the processor 220 of the electronic apparatus 200 is a multi-core processor, a plurality of cores, for example, cores C1, C2, C3 and C4, may be included in the processor 220, as a non-limiting example. For example, the processor 22 may include more or fewer cores than 4, such as 2 cores, 8 cores, or another number of cores.

In such an example, the core C1 may directly determine its own LVcc. Also, in a non-limiting example, the cores C1, C2, C3 and C4 may each directly determine their own LVcc at the same time. In another non-limiting example, the cores C1, C2, C3 and C4 may each directly determine their own LVcc in a preset sequence. A core that does not determine its own LVcc may monitor a state of a core that determines its own LVcc. During a process by which the core C1 directly determines its own LVcc, a system may be shut down. In such an example, the core C1 may be reset by another core.

In another example, a core may determine LVcc of another core. For example, during a first time interval, the core C2 may determine LVcc of the core C1 and the core C4 may determine LVcc of the core C3. During a second time interval, the core C1 may determine LVcc of the core C2 and the core C3 may determine LVcc of the core C4.

A voltage supplied to the core C1 may differ from a voltage supplied to the core C2, based on separating a power domain of the core C1 from a power domain of the core C2. A safety of a system may be ensured by separating power domains in this matter.

FIG. 5 is a flowchart illustrating a method of monitoring a target semiconductor chip and resetting the target semiconductor chip, according to one or more examples.

In one or more examples, operation 510 of FIG. 5 may be performed after operation 330 of FIG. 3 is performed.

In operation 510, the electronic apparatus 200 may monitor the target semiconductor chip. For example, whether the target semiconductor chip generates a result may be monitored. When the target semiconductor chip is shut down, the result may not be generated.

In operation 520, the electronic apparatus 200 may resets the target semiconductor chip when the target semiconductor chip is not normal. Such a resetting represents an attempt to resolve the abnormal operation of the semiconductor chip.

The target semiconductor chip may operate normally under the first voltage and may not operate normally under the second voltage. Thus, the first voltage may be determined as being the LVcc of the target semiconductor chip.

FIG. 6 illustrates a method by which an electronic apparatus determines an LVcc of a semiconductor chip of another electronic apparatus, according to one or more examples.

Referring to FIG. 6, an electronic apparatus 200 may determine an LVcc of a target semiconductor chip 600 of another electronic apparatus. As a non-limiting example, the electronic apparatus 200 may be a hardware apparatus separate from the other electronic apparatus. For example, the electronic apparatus 200 may be an apparatus used for checking a safety function of an apparatus including the electronic apparatus 200.

The electronic apparatus 200 may monitor a state of the target semiconductor chip 600. For example, whether the target semiconductor chip 600 is in a normal state may continue to be monitored by the electronic apparatus 200 on an ongoing basis.

When the target semiconductor chip 600 is not in the normal state, the electronic apparatus 200 may reset the target semiconductor chip 600, in an attempt to cause the target semiconductor 600 to resume operation in the normal state.

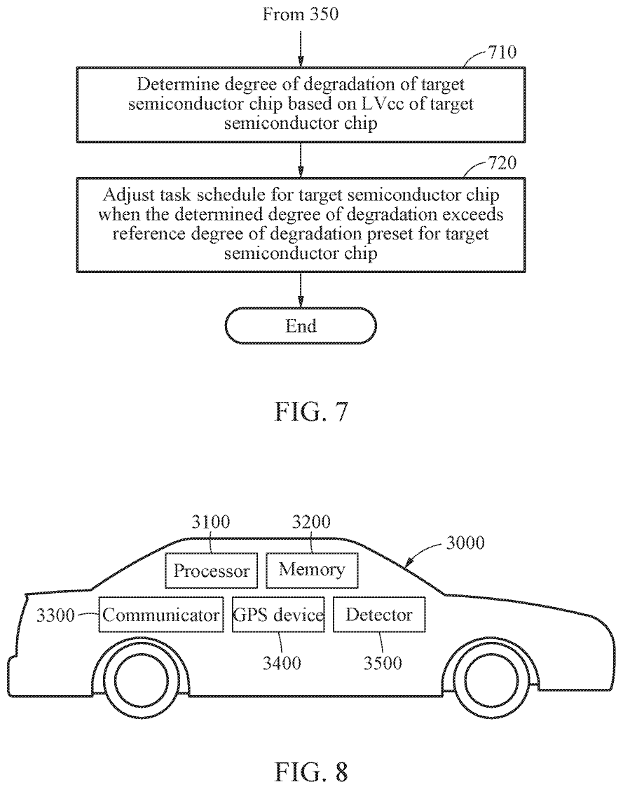

FIG. 7 is a flowchart illustrating a method of adjusting a task schedule of a target semiconductor chip based on an LVcc of the target semiconductor chip, according to one or more examples.

The electronic apparatus 200 may further perform operations 710 and 720 of FIG. 7, after performing operation 350 of FIG. 3, in order to increase a lifetime of the target semiconductor chip, based on an LVcc of the target semiconductor chip.

In operation 710, the electronic apparatus 200 may measure a degree of degradation of the target semiconductor chip, based on an LVcc of the target semiconductor chip. For example, a lifetime graph may be generated based on LVcc of the target semiconductor chip, and a wear rate or a life expectancy of the target semiconductor chip may be measured as an indicator of a degree of degradation.

In operation 720, the electronic apparatus 200 may adjust a task schedule for the target semiconductor chip, when the determined degree of degradation exceeds a reference degree of degradation. The reference degree of degradation may be preset for the target semiconductor chip. For example, when the target semiconductor chip has degraded characteristics in comparison to another target semiconductor chip, the task schedule may be adjusted by reducing a number of tasks of the target semiconductor chip. By adjusting the task schedule, degrees of deterioration of a plurality of semiconductor chips may be maintained to be similar.

FIG. 8 illustrates a configuration of a vehicle 3000 including an electronic apparatus 200, according to one or more examples.

Referring to FIG. 8, the electronic apparatus 200 may be mounted on the vehicle 3000 or may otherwise be integrated or associated with the vehicle 3000. For example, the vehicle 3000 may be an autonomous vehicle or a vehicle that supports an advanced driver assistance system (ADAS), as non-limiting examples, but the vehicle 3000 is not limited to these enumerated types of vehicle 3000.

The vehicle 3000 may include a processor 3100, a memory 3200, a communicator 3300, a global positioning system (GPS) device 3400, and a detector 3500, according to a non-limiting example.

The processor 3100, the memory 3200 and the communicator 3300 may respectively correspond to the processor 220, the memory 230 and the communicator 210 described above with reference to the examples of FIGS. 2 and 3. The processor 3100 may control overall operations of various components included in the vehicle 3000.

For example, the electronic apparatus 200 may include the processor 3100, the memory 3200 and the communicator 3300. For example, when a determined current point in time is chosen as a preset target point in time, the electronic apparatus 200 may perform the method of FIG. 3 through performing operations 310 through 350. In an example, the target point in time may be included in a sequence in which the electronic apparatus 200 or the vehicle 3000 is powered off. In another example, the target point in time may be included within a preset time interval after the electronic apparatus 200 or the vehicle 3000 is powered off.

For example, the processor 3100 may communicate with an external electronic apparatus, such as another mobile device or another system, via the communicator 3300. The processor 3100 may acquire information associated with a position of the vehicle 3000 based on a signal received from the GPS device 3400. Also, the processor 3100 may acquire information associated with an environment around the vehicle 3000, based on a signal received from the detector 3500.

For example, the processor 3100 may operate as an electronic control unit (ECU) of the vehicle 3000. To control a movement of the vehicle 3000, the processor 3100 may operate as an anti-lock breaking system (ABS), a traction control system (TCS), a vehicle dynamic control (VDC) or a tire-pressure monitoring system (TPMS), as non-limiting examples. In other examples, the processor 3100 may manipulate data and output control signals to manage other systems of the vehicle 3000 in a way that controls the vehicle. The processor 3100 may control an operation of the vehicle 3000 based on data provided from an air flow sensor (AFS), a throttle position sensor (TPS), an air temperature sensor (ATS), a barometric pressure sensor (BPS), a crank angle sensor (CAS) or an idle speed controller (ISC), as non-limiting examples. However, in other examples, the processor 3100 may use other sensors.

The processor 3100 may perform operations to determine each LVcc of the components of the vehicle 3000. Also, the processor 3100 may perform operations for balancing degrees of degradation of the components. The operations to determine each LVcc of the components and the operations for balancing the degrees of degradation of the components are similar to those described above with reference to FIGS. 3 through 7, and thus further description thereof is omitted for brevity.

The memory 3200 may be, for example, a storage device. The memory 3200 may store data that is processed or to be processed by the processor 3100. For example, the memory 3200 may store data associated with a movement, a posture and a position of the vehicle or the environment around the vehicle 3000, as non-limiting examples.

The communicator 3300 may also communicate with an electronic apparatus outside the vehicle 3000, another vehicle, and a system, based on various protocols.

The GPS device 3400 may receive a signal associated with the position of the vehicle 3000 from, for example, a satellite, as a non-limiting example. However, the GPS device may receive signals used to derive the position of the vehicle from other sources than a satellite, in other examples. The GPS device 3400 may generate a signal indicating position information of the vehicle 3000, based on the received signal. The detector 3500 may include devices used to acquire information associated with the environment around the vehicle 3000. For example, the detector 3500 may include devices such as a radar, a lidar, an infrared detector, or an image capturing device, as non-limiting examples.

The electronic apparatuses, electronic apparatus 200, communicators, communicator 210, processors, processor 220, memories, memory 230, target semiconductor chips, target semiconductor chip 600, vehicles, vehicle 3000, processor 3100, memory 3200, communicator 3300, GPS devices, GPS device 3400, detectors, detector 3500, apparatuses, units, modules, devices, and other components described herein are implemented by hardware components configured to perform the operations described in this application that are performed by the hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-8 that perform the operations described in this application are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above are written as computer programs, code segments, instructions or any combination thereof, for individually or collectively instructing or configuring the one or more processors or computers to operate as a machine or special-purpose computer to perform the operations performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computers using an interpreter. The instructions or software may be written using any programming language based on the block diagrams and the flow charts illustrated in the drawings and the corresponding descriptions in the specification, which disclose algorithms for performing the operations performed by the hardware components and the methods as described above.

The instructions or software to control computing hardware, for example, one or more processors or computers to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD−ROMs, CD−Rs, CD+Rs, CD−RWs, CD+RWs, DVD−ROMs, DVD−Rs, DVD+Rs, DVD−RWs, DVD+RWs, DVD−RAMs, BD−ROMs, BD−Rs, BD−R LTHs, BD−REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to a processor or computer so that the processor or computer can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A processor-implemented method performed by an electronic apparatus, comprising:
determining a second voltage obtained by reducing a first voltage by a voltage having a preset magnitude;
controlling a target semiconductor chip such that the target semiconductor chip performs a preset target task based on the second voltage;
determining whether a result of the target task is the same as a reference result preset for the target task; and
determining the first voltage as being a low supply voltage of the target semiconductor chip, in response to the result differing from the reference result.

2. The method of claim 1, wherein the target semiconductor chip comprises one or more processors of the electronic apparatus or one or more processors of another electronic apparatus.

3. The method of claim 2, wherein in response to the one or more processors comprising a multi-core processor, the target semiconductor chip comprises a first core of the multi-core processor and the low supply voltage of the target semiconductor chip is determined by a second core of the multi-core processor.

4. The method of claim 2, wherein the one or more processors comprise a central processing unit (CPU).

5. The method of claim 1, wherein the target semiconductor chip comprises a memory of the electronic apparatus or a memory of another electronic apparatus.

6. The method of claim 5, wherein the memory of the electronic apparatus comprises a cache memory.

7. The method of claim 1, wherein the electronic apparatus is fabricated as a system on chip (SoC).

8. The method of claim 1, wherein the electronic apparatus is mounted on a vehicle.

9. The method of claim 1, further comprising:
resetting the target semiconductor chip, in response to the target semiconductor chip failing to generate a result of the preset target task.

10. The method of claim 1, further comprising:
determining a degree of degradation of the target semiconductor chip based on the low supply voltage of the target semiconductor chip; and
adjusting a task schedule for the target semiconductor chip, in response to the degree of degradation exceeding a reference degree of degradation preset for the target semiconductor chip.

11. The method of claim 1, wherein the method is performed in response to a determined current point in time being a preset target point in time.

12. The method of claim 11, wherein the target point in time is included in a sequence of points in time in which the electronic apparatus is powered off.

13. A non-transitory computer-readable storage medium storing instructions that, when executed by a processor, cause the processor to perform the method of claim 1.

14. An electronic apparatus, the electronic apparatus comprising:
one or more processors configured to:
determine a second voltage obtained by reducing a first voltage by a voltage having a preset magnitude;
control a target semiconductor chip such that the target semiconductor chip performs a preset target task based on the second voltage;
determine whether a result of the target task is the same as a reference result preset for the target task; and
determine the first voltage as a low supply voltage of the target semiconductor chip, in response to the result being different from the reference result.

15. The electronic apparatus of claim 14, wherein the target semiconductor chip comprises a processor of the electronic apparatus or a processor of another electronic apparatus.

16. The electronic apparatus of claim 15, wherein in response to the one or more processors comprising a multi-core processor, the target semiconductor chip is a first core of the multi-core processor and the low supply voltage of the target semiconductor chip is determined by a second core of the multi-core processor.

17. The electronic apparatus of claim 15, wherein the one or more processors comprise a central processing unit (CPU).

18. The electronic apparatus of claim 14, wherein the target semiconductor chip comprises a memory of the electronic apparatus or a memory of another electronic apparatus.

19. The electronic apparatus of claim 14, wherein the electronic apparatus is mounted on a vehicle.

20. The method of claim 14, wherein the one or more processors are further configured to perform resetting the target semiconductor chip, in response to the target semiconductor chip failing to generate a result of the preset target task.

21. The apparatus of claim 14, further comprising a memory storing instructions, which, when executed by the one or more processors, configure the one or more processors to perform the determination of the second voltage, the controlling, the determination of whether a result of the target task is the same as a reference result, and the determination of the first voltage.
